(19) United States
(12) Patent Application Publication
(10) Pub. No.: US 2025/0391685 A1
(43) Pub. Date: Dec. 25, 2025

(54) SUBSTRATE MAPPING SENSOR AND ELECTRONIC DEVICE

(71) Applicants: Samsung Display Co., Ltd., Yongin-Si (KR); JINOID Co., LTD, Seoul (KR)

(72) Inventors: Min Chul JUNG, Yongin-si (KR); Jong Jin PARK, Seoul (KR); Hyun Hoo SEO, Yongin-si (KR); Ji Hwan CHO, Seoul (KR)

(21) Appl. No.: 19/217,152

(22) Filed: May 23, 2025

(30) Foreign Application Priority Data
Jun. 21, 2024 (KR) 10-2024-0081208
Nov. 6, 2024 (KR) 10-2024-0155766

(51) Int. Cl. H01L 21/67

(52) U.S. Cl. CPC H01L 21/67288; H01L 21/67265

(57) ABSTRACT

A substrate mapping sensor detects a state of a substrate located in a channel within a cassette and includes a light transmitting unit located on a side of the cassette and a light receiving unit located on another side of the cassette. The light transmitting unit includes a first light transmitting unit and a second light transmitting unit, which are a pair and located on a side of the channel, the light receiving unit includes a first light receiving unit and a second light receiving unit, which are a pair and located on another side of the channel, the first light transmitting unit and the first light receiving unit detect a presence or an absence of the substrate in the channel, and the second light transmitting unit and the second light receiving unit detect a sagging state of the substrate in the channel.

### CROSS-REFERENCE TO RELATED APPLICATION

The application claims priority to and the benefit of Korean Patent Application No. 10-2024-0081208 filed on Jun. 21, 2024 and 10-2024-0155766, filed on Nov. 6, 2024, which is hereby incorporated by reference for all purposes as if fully set forth herein.

### BACKGROUND

### Field

This disclosure relates to a substrate mapping sensor and an electronic device.

### Discussion

As interest in information displays has increased recently, research and development on display devices and devices for manufacturing them are continuously being conducted.

### SUMMARY

In accordance with the inventive concept, a substrate mapping sensor capable of detecting not only a presence or an absence of a substrate but also a sagging state and degree of the substrate is presented.

The inventive concept is not limited to the technical features mentioned above, and other technical features not mentioned will be clearly understood by those skilled in the art from the description below.

In an embodiment, a substrate mapping sensor according to embodiments may detect a state of a substrate located in a channel within a cassette. The substrate mapping sensor may include a light transmitting unit located on a side of the cassette; and a light receiving unit located on another side of the cassette. The light transmitting unit may include a first light transmitting unit and a second light transmitting unit, which are a pair and located on a side of the channel, the light receiving unit may include a first light receiving unit and a second light receiving unit, which are a pair and located on another side of the channel, the first light transmitting unit and the first light receiving unit may detect a presence or an absence of the substrate in the channel, and the second light transmitting unit and the second light receiving unit may detect a sagging state of the substrate in the channel.

The first light transmitting unit and the first light receiving unit may face each other in a first direction with the channel interposed therebetween.

The first light transmitting unit may include one light transmitting element.

The first light receiving unit may include one light receiving element.

The second light transmitting unit and the second light receiving unit may face each other in a first direction with the channel interposed therebetween.

The second light transmitting unit may include first, second, and third light transmitting elements.

The second light receiving unit may include first, second, third, fourth, and fifth light receiving elements.

The sagging state of the substrate may be determined by a displacement value of an amount of light reaching the second light receiving unit.

A sagging detection area of the substrate may be 5 mm to 13 mm based on a normally loaded substrate.

A distance between a first side of the substrate and the light transmitting unit may be 150 mm or less.

A distance between a second side of the substrate and the light receiving unit may be 150 mm or less.

The light receiving unit may further include a first indicator light indicating the presence or the absence of the substrate and a second indicator light indicating the sagging state of the substrate.

A light source of the light transmitting unit may be infrared.

A light receiving element of the light receiving unit may be a photodiode.

An electronic device according to embodiments may include a processor; and a display device including pixels and configured to display an image by the pixels under the control of the processor. A state of a substrate of the display device may be detected by a substrate mapping sensor comprising a light transmitting unit located on a side of a cassette and a light receiving unit located on another side of the cassette. The light transmitting unit includes a first light transmitting unit and a second light transmitting unit, which are a pair and located on a side of a channel. The light receiving unit includes a first light receiving unit and a second light receiving unit, which are a pair and located on another side of the channel. The first light transmitting unit and the first light receiving unit detect a presence or an absence of the substrate in the channel. The second light transmitting unit and the second light receiving unit detect a sagging state of the substrate in the channel.

Specific details of other embodiments are included in the detailed description and accompanying drawings.

### BRIEF DESCRIPTION OF THE DRAWINGS

The accompanying drawings, which are included to provide a further understanding of the inventive concepts, and are incorporated in and constitute a part of this specification, illustrate exemplary embodiments of the inventive concepts, and, together with the description, serve to explain principles of the inventive concepts.

FIG. 1 is a perspective view illustrating a state in which a substrate mapping sensor according to an embodiment is installed.

FIG. 2 is a perspective view of a cassette according to an embodiment.

FIG. 3 is a side view of the substrate mapping sensor according to an embodiment.

FIGS. 4, 5, 6, and 7 are side views for explaining a method by which the substrate mapping sensor according to an embodiment detects sagging of a substrate.

FIG. 8 is a side view for explaining an indicator light provided in a light receiving unit according to an embodiment.

FIG. 9 is a block diagram of an electronic device according to an embodiment.

FIG. 10 is a schematic diagram illustrating electronic devices according to various embodiments.

### DETAILED DESCRIPTION OF THE ILLUSTRATED EMBODIMENTS

Hereinafter, embodiments of the inventive concept will be described in more detail with reference to the accompanying drawings. It should be noted that in the following description, only the parts necessary to understand the operation according to the inventive concept will be described, and descriptions of other parts will be omitted in order to not obscure the gist of the inventive concept.

The inventive concept is not limited to the embodiments described herein and may be embodied in other forms. The embodiments described herein are provided merely to explain in detail enough to enable those skilled in the art to easily implement the technical idea of the inventive concept.

Throughout the specification, in a case where a portion is “connected” to another portion, the case includes not only a case where the portion is “directly connected” but also a case where the portion is “indirectly connected” with another element interposed therebetween. Terms used herein are for describing specific embodiments and are not intended to limit the inventive concept.

Throughout the specification, in a case where a certain portion “includes”, the case means that the portion may further include another component without excluding another component unless otherwise stated. “At least any one of X, Y, and Z” and “at least any one selected from a group consisting of X, Y, and Z” may be interpreted as one X, one Y, one Z, or any combination of two or more of X, Y, and Z (for example, XYZ, XYY, YZ, and ZZ). Here, “and/or” includes all combinations of one or more of corresponding configurations.

Here, terms such as first and second may be used to describe various components, but these components are not limited to these terms. These terms are used to distinguish one component from another component. Therefore, a first component may refer to a second component within a range without departing from the scope disclosed herein.

Spatially relative terms such as “under”, “on”, and the like may be used for descriptive purposes, thereby describing the relationship between one element or feature and another element(s) or feature(s) as shown in the drawings. Spatially relative terms are intended to include other directions in use, in operation, and/or in manufacturing, in addition to the first direction (DR1), second direction (DR2), and third direction (DR3) depicted in the drawings.

When a device shown in the drawing is turned upside down, elements depicted as being positioned “under” other elements or features are positioned in a direction “on” the other elements or features. Therefore, in an embodiment, the term “under” may include both directions of on and under. In addition, the device may face in other directions (for example, rotated 90 degrees or in other directions) and thus the spatially relative terms used herein are interpreted according thereto.

Various embodiments are described with reference to drawings schematically illustrating ideal embodiments. Accordingly, it will be expected that shapes may vary, for example, according to tolerances and/or manufacturing techniques. Therefore, the embodiments disclosed herein cannot be construed as being limited to shown specific shapes, and should be interpreted as including, for example, changes in shapes that occur as a result of manufacturing. As described above, the shapes shown in the drawings may not show actual shapes of areas of a device, and the present embodiments are not limited thereto.

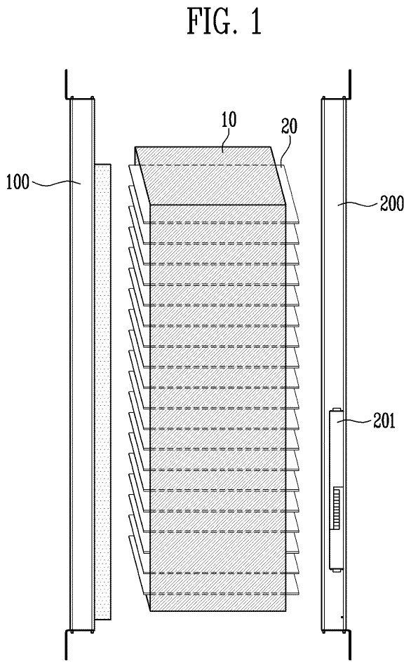

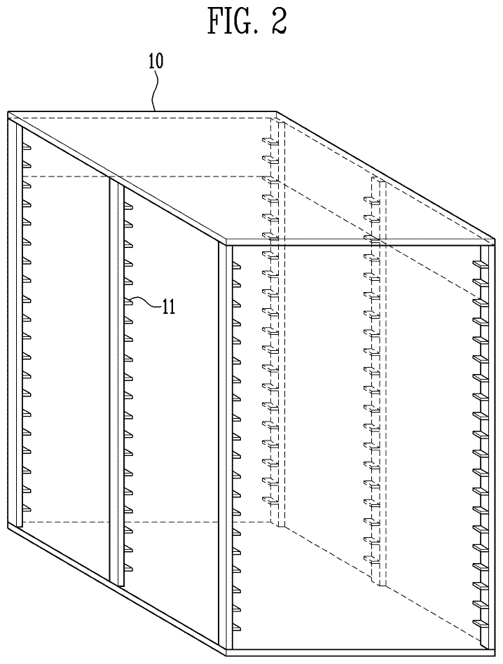

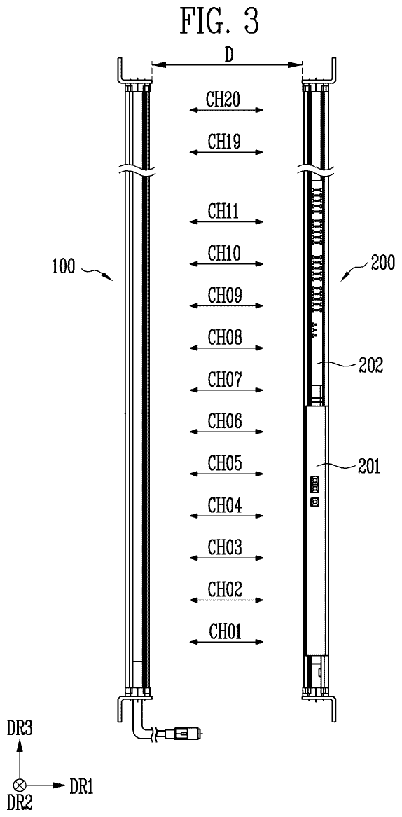

FIG. 1 is a perspective view illustrating a state in which a substrate mapping sensor 100 and 200 according to an embodiment is installed. FIG. 2 is a perspective view of a cassette 10 according to an embodiment. FIG. 3 is a side view of the substrate mapping sensor 100 and 200 according to an embodiment.

Referring to FIGS. 1 to 3, the substrate mapping sensor 100 and 200 may detect the state of a substrate 20 located in each of channels CH01 to CH20 within the cassette 10. The substrate 20 may be transparent glass and/or opaque glass, but the inventive concept is not necessarily limited thereto.

The substrate mapping sensor 100 and 200 may detect not only the presence or absence of the substrate 20 in each of the channels CH01 to CH20, but also the sagging state and degree of the substrate 20 in each of the channels CH01 to CH20. Although the drawings show an embodiment in which the number of channels CH01 to CH20 (or optical axes) is 20, the inventive concept is not necessarily limited thereto and may be modified in various ways.

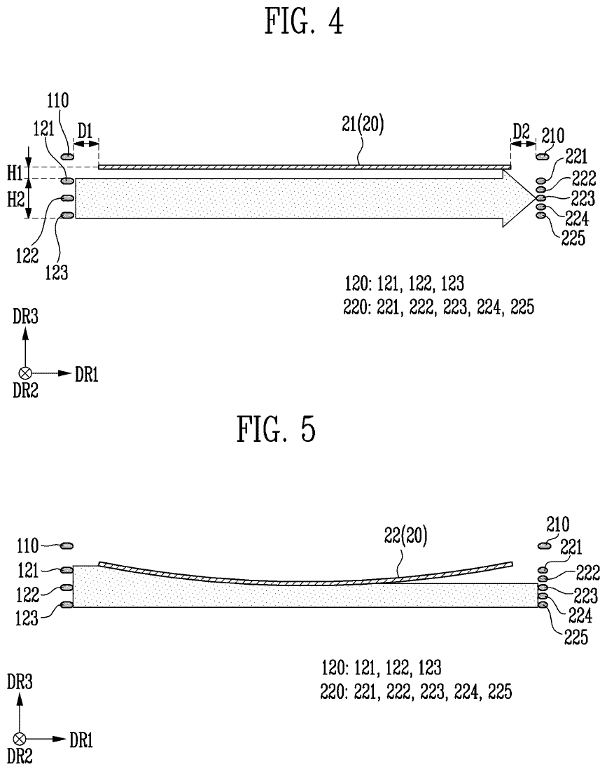

Each substrate 20 may be supported by a support bar 11 provided in the cassette 10. Each substrate 20 may be loaded or stored on the support bar 11. If the support bar 11 supporting the substrate 20 is deformed or sags, the substrate 20 loaded on the support bar 11 may sag and the substrate 20 may collide with a substrate loading robot, resulting in damage to the substrate 20. Accordingly, the substrate mapping sensor 100 and 200 according to an embodiment may detect not only the presence or absence of the substrate 20 but also the sagging state and degree of the substrate 20 in real time, thereby preventing damage to the substrate 20 due to sagging of the support bar 11 and the substrate 20. A detailed description of this will be described later with reference to FIGS. 4 to 7.

The substrate mapping sensor 100 and 200 may be an optical sensor using a light transmitting method and a light receiving method. The substrate mapping sensor 100 and 200 may include a light transmitting unit 100 and a light receiving unit 200. The light transmitting unit 100 may be located on a side of the cassette 10. The light receiving unit 200 may be located on another side of the cassette 10. The distance D between the light transmitting unit 100 and the light receiving unit 200 in a first direction DR1 (e.g., a horizontal direction) may be 0.8 m to 1.8 m. However, the inventive concept is not necessarily limited thereto, and the distance D between the light transmitting unit 100 and the light receiving unit 200 in the first direction DR1 (or the horizontal direction) may be variously adjusted depending on the size of the cassette 10.

The light transmitting unit 100 may irradiate a detection beam, and the detection beam may be received by the light receiving unit 200. A light source of the light transmitting unit 100 may be infrared. For example, the light source of the light transmitting unit 100 may have a wavelength of 850 nm, but the inventive concept is not necessarily limited thereto. A light receiving element of the light receiving unit 200 may be a photodiode. However, the inventive concept is not necessarily limited thereto and may be variously changed according to embodiments.

FIGS. 4 to 7 are side views for explaining a method by which the substrate mapping sensor according to an embodiment detects sagging of a substrate.

Referring to FIGS. 1 to 7, the light transmitting unit 100 may include a first light transmitting unit 110 and a second light transmitting unit 120, which are a pair and located on a side of each of the channels CH01 to CH20 (or the substrate 20).

The distance between the first light transmitting unit 110 and the second light transmitting unit 120 of adjacent pairs, that is, an optical axis pitch, may be 56 mm, but the inventive concept is not necessarily limited thereto. The number of pairs of the first light transmitting unit 110 and the second light transmitting unit 120, that is, the number of optical axes, may be 20, but the inventive concept is not necessarily limited thereto. According to an embodiment, the number of optical axes may be 26 or may be variously changed.

The distance D1 between the light transmitting unit 100 (the first light transmitting unit 110 and/or the second light transmitting unit 110) and a first side of the substrate 20 in the first direction DR1 (or the horizontal direction) may be 150 mm or less, but the inventive concept is not necessarily limited thereto.

The pair of the first light transmitting unit 110 and the second light transmitting unit 120 may be provided at positions corresponding to one of the channels CH01 to CH20. As an example, the pair of the first light transmitting unit 110 and the second light transmitting unit 120 may be aligned with one of the channels CH01 to CH20 in the first direction DR1 (or the horizontal direction).

The light receiving unit 200 may include a first light receiving unit 210 and a second light receiving unit 220, which are a pair and located on another side of each of the channels CH01 to CH20 (or the substrate 20).

The distance between the first light receiving unit 210 and the second light receiving unit 220 of adjacent pairs, that is, an optical axis pitch, may be 56 mm, but the inventive concept is not necessarily limited thereto. The number of pairs of the first light receiving unit 210 and the second light receiving unit 220, that is, the number of optical axes, may be 20, but the inventive concept is not necessarily limited thereto. According to an embodiment, the number of optical axes may be 26 or may be variously changed.

The distance D2 between the light receiving unit 200 (the first light receiving unit 210 and/or the second light receiving unit 220) and a second side of the substrate 20 in the first direction DR1 (or the horizontal direction) may be 150 mm or less, but the inventive concept is not necessarily limited thereto.

The pair of the first light receiving unit 210 and the second light receiving unit 220 may be provided at positions corresponding to one of the channels CH01 to CH20. As an example, the pair of the first light receiving unit 210 and the second light receiving unit 220 may be aligned with one of the channels CH01 to CH20 in the first direction DR1 (or the horizontal direction).

The first light transmitting unit 110 and the first light receiving unit 210 may detect the presence or absence of the substrate 20 in each of the channels CH01 to CH20. As an example, the first light transmitting unit 110 and the first light receiving unit 210 may be sensors which determine the presence or absence of the substrate 20 in each of the channels CH01 to CH20.

The first light transmitting unit 110 and the first light receiving unit 210 may face each other in the first direction DR1 (or the horizontal direction) with each channel CH01 to CH20. Each channel CH01 to CH20 may be disposed between the first light transmitting unit 110 and the first light receiving unit 210. A detection beam irradiated from a light transmitting element of the first light transmitting unit 110 may have a selected detection width. For example, the detection beam irradiated from the light transmitting element of the first light transmitting unit 110 may be irradiated to have a detection width wider than the thickness of the substrate 20 loaded in the cassette 10. If the substrate 20 exists in each of the channels CH01 to CH20, the presence or absence of the substrate 20 may be determined using the reduced amount of light passing through the substrate 20.

The first light transmitting unit 110 may include one light transmitting element. The first light receiving unit 210 may include one light receiving element. However, the inventive concept is not necessarily limited thereto, and the number of light transmitting elements of the first light transmitting unit 110 and the number of light receiving elements of the first light receiving unit 210 may be changed according to embodiments.

The second light transmitting unit 120 and the second light receiving unit 220 may detect the sagging state of the substrate 20 in each of the channels CH01 to CH20. As an example, the second light transmitting unit 120 and the second light receiving unit 220 may be sensors which determine the sagging state of the substrate 20 in each of the channels CH01 to CH20. The second light transmitting unit 120 and the second light receiving unit 220 may face each other in the first direction DR1 (or the horizontal direction) with each channel CH01 to CH20. Each channel CH01 to CH20 may be disposed between the second light transmitting unit 120 and the second light receiving unit 220.

The second light transmitting unit 120 may include first to third light transmitting elements 121, 122, and 123. The second light receiving unit 220 may include first to fifth light receiving elements 221, 222, 223, 224, and 225. The sagging state of the substrate 20 in each of the channels CH01 to CH20 may be determined by a displacement value of the amount of light reaching the first to fifth light receiving elements 221, 222, 223, 224, and 225 of the second light receiving unit 220.

Referring to FIG. 4, if a substrate 21 is normally loaded, 100% of the amount of light irradiated from the second light transmitting unit 120 may reach the second light receiving unit 220. For example, detection beams irradiated from the first to third light transmitting elements 121, 122, and 123 of the second light transmitting unit 120 may reach all of the first to fifth light receiving elements 221, 222, 223, 224, and 225 of the second light receiving unit 220.

Referring to FIGS. 5 to 7, as described above, sagging of the support bar 11 may cause sagging of substrates 22, 23, and 24. In this case, the amount of light equivalent to portions blocked by the sagging substrates 22, 23, and 24 may reach the second light receiving unit 220.

For example, in the case of the substrate 22 of FIG. 5, which has a relatively low sagging degree, 60% of the amount of light irradiated from the second light transmitting unit 120 may reach the second light receiving unit 220. For example, detection beams irradiated from the first to third light transmitting elements 121, 122, and 123 of the second light transmitting unit 120 may reach some of the first to fifth light receiving elements 221, 222, 223, 224, and 225 of the second light receiving unit 220. As an example, the detection beams irradiated from the first to third light transmitting elements 121, 122, and 123 of the second light transmitting unit 120 may be blocked by the sagging portion of the substrate 22 and thus may not reach the first and second light receiving elements 221 and 222, but may only reach the third to fifth light receiving elements 223, 224, and 225.

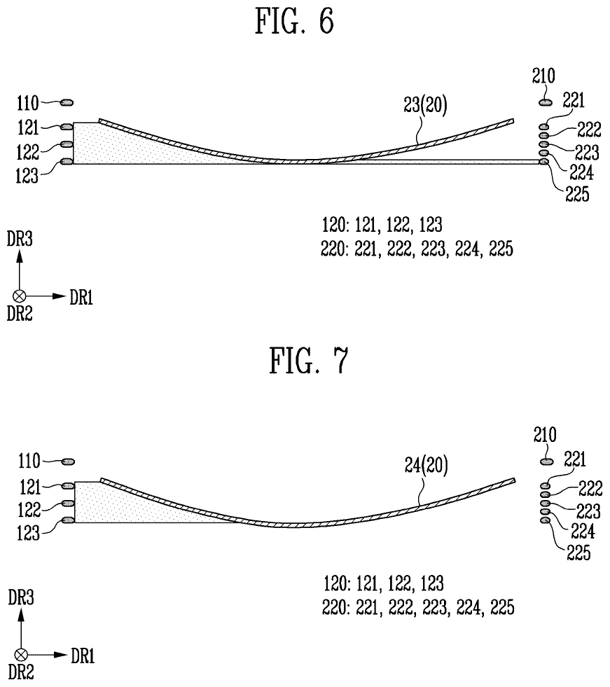

In the case of the substrate 23 of FIG. 6, which is more sagging than the substrate 22 of FIG. 5, 20% of the amount of light irradiated from the second light transmitting unit 120 may reach the second light receiving unit 220. For example, the detection beams irradiated from the first to third light transmitting elements 121, 122, and 123 of the second light transmitting unit 120 may reach some of the first to fifth light receiving elements 221, 222, 223, 224, and 225 of the second light receiving unit 220. As an example, the detection beams irradiated from the first to third light transmitting elements 121, 122, and 123 of the second light transmitting unit 120 may be blocked by the sagging portion of the substrate 23 and thus may not reach the first to fourth light receiving elements 221, 222, 223, and 224, but may only reach the fifth light receiving element 225.

In the case of the substrate 24 of FIG. 7, which is more sagging than the substrate 23 of FIG. 6, all of the detection beams irradiated from the second light transmitting unit 120 may not reach the second light receiving unit 220. For example, the detection beams irradiated from the first to third light transmitting elements 121, 122, and 123 of the second light transmitting unit 120 may not reach any of the first to fifth light receiving elements 221, 222, 223, 224, and 225 of the second light receiving unit 220. As an example, the detection beams irradiated from the first to third light transmitting elements 121, 122, and 123 of the second light transmitting unit 120 may be blocked by the sagging portion of the substrate 24 and thus may not reach any of the first to fifth light receiving elements 221, 222, 223, 224, and 225.

As in the method described above, the sagging state and degree of the substrate 20 may be determined by the displacement value of the amount of light reaching the second light receiving unit 220.

In an embodiment, a sagging detection area of the substrate 20 in the substrate mapping sensor 100 and 200 may be 5 mm to 13 mm based on the normally loaded substrate 21. For example, a distance H1, e.g., see FIG. 4, between the normally loaded substrate 21 and the first light transmitting element 121 in a third direction DR3 (e.g., a vertical direction perpendicular to the first direction DR1 and perpendicular to a second direction DR2 crossing the first direction DR1) may be 5 mm or more. A distance H2, e.g., see FIG. 4, between the first light transmitting element 121 and the third light transmitting element 123 in the third direction DR3 (or the vertical direction) may be 13 mm or less. However, the inventive concept is not necessarily limited thereto, and the distances H1 and H2 may be variously changed depending on the sagging degree of the substrate 20 detected by the substrate mapping sensor 100 and 200.

In the drawings, an embodiment in which the second light transmitting unit 120 includes three light transmitting elements 121, 122, and 123 and the second light receiving unit 220 includes five light receiving elements 221, 222, 223, 224, and 225 is shown as an example. However, the inventive concept is not necessarily limited thereto and the number of light transmitting elements and the number of light receiving elements may be changed according to embodiments.

As described above, the substrate mapping sensor 100 and 200 according to the embodiments may not only detect the presence or absence of the substrate 20 in each of the channels CH01 to CH20 using the first light transmitting unit 110 and the first light receiving unit 210, but may also determine the sagging state and degree of the substrate 20 in each of the channels CH01 to CH20 in real time using the displacement value of the amount of light reaching the second light receiving unit 220. Therefore, it is possible to prevent the substrate 20 from being damaged by collision with the substrate loading robot due to sagging of the substrate 20. Accordingly, a slot pitch margin of the cassette 10 can be minimized, so that the number of substrates 20 to be loaded can be increased.

In addition, the substrate mapping sensor 100 and 200 according to the embodiments may determine not only the presence or absence of the substrate 20, but also the sagging state and degree of the substrate 20 due to sagging of the support bar 11 using one light transmitting unit 100 and one light receiving unit 200. Therefore, there is no need to separately configure a cassette tester to test the sagging of the support bar 11, so there is an advantage in that installation space and installation costs can be minimized.

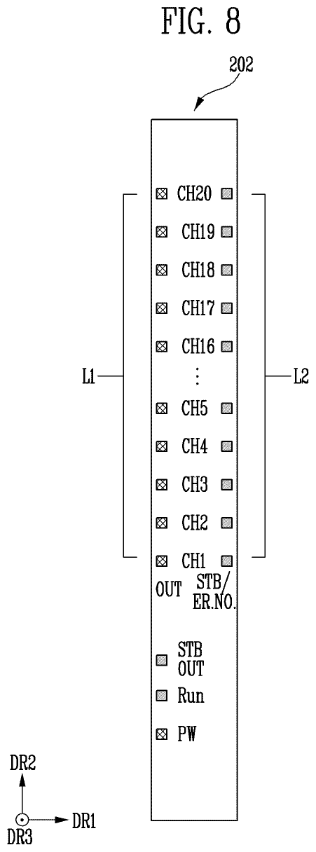

FIG. 8 is a side view for explaining an indicator light provided in a light receiving unit according to an embodiment.

The state of the substrate 20 detected as described above may be easily checked through a communication module 201, e.g., see FIG. 1, and an indicator light 202 provided in the light receiving unit 200. The communication module 201 may output the presence or absence of the substrate 20 in each of the channels CH01 to CH20 and output the sagging detection of the substrate 20 in each of the channels CH01 to CH20. As an example, the communication module 201 may be a CC-LINK, but the inventive concept is not necessarily limited thereto.

The indicator light 202 may include a first indicator light L1 indicating the presence or absence of the substrate 20 in each of the channels CH01 to CH20 and a second indicator light L2 indicating the sagging detection of the substrate 20 in each of the channels CH01 to CH20. According to an embodiment, the indicator light 202 may further include an indicator light STB OUT which lights up when there is no sagging detection of the substrate 20 in all channels CH01 to CH20, an indicator light Run which lights up when the substrate mapping sensor 100 and 200 is operating normally, an indicator light PW which lights up when a power source is supplied, and the like.

In an embodiment, the substrate 20 described above may constitute a substrate of a display device. The display device according to the embodiment may be applied to various electronic devices. An electronic device according to an embodiment may include the display device, and may further include a module or device having additional functions in addition to the display device.

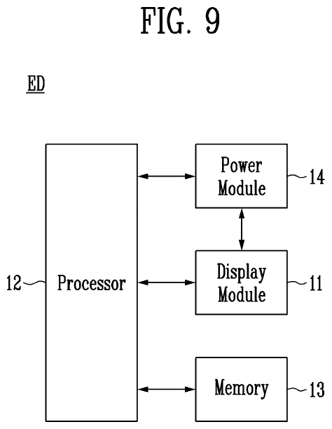

FIG. 9 is a block diagram of an electronic device ED according to an embodiment. Referring to FIG. 9, the electronic device ED according to an embodiment may include a display module 11, a processor 12, a memory 13, and a power source module 14.

The processor 12 may include at least one of a central processing unit (CPU), an application processor (AP), a graphics processing unit (GPU), a communication processor (CP), an image signal processor (ISP), or a controller.

The memory 13 may store data information necessary for the operation of the processor 12 or the display module 11. If the processor 12 executes an application stored in the memory 13, an image data signal and/or an input control signal may be transmitted to the display module 11, and the display module 11 may process the received signals and output image information through a display screen.

The power source module 14 may include a power source supply module, such as a power source adapter or a battery device, and a power source conversion module which converts a power source supplied by the power source supply module to generate power sources required for the operation of the electronic device 10.

At least one of components of the electronic device ED described above may be included in the display device according to the embodiments described above. In addition, some of individual modules functionally included within one module may be included within the display device, while others may be provided separately from the display device. For example, the display device may include the display module 11, and the processor 12, the memory 13, and the power source module 14 may be provided in the form of other devices within the electronic device ED other than the display device.

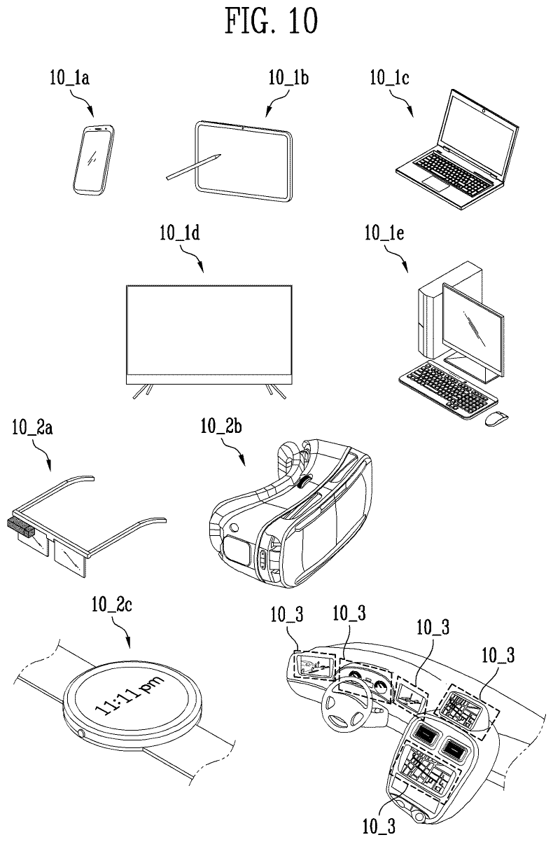

FIG. 10 is a schematic diagram illustrating electronic devices according to various embodiments.

Referring to FIG. 10, various electronic devices to which the display device according to the embodiments is applied may include not only electronic devices for displaying images, such as a smart phone 10_1a, a tablet PC 10_1b, a laptop 10_1c, TV 10_1d, and a desk monitor 10_1e, but also wearable electronic devices including display modules, such as smart glasses 10_2a, a head-mounted display 10_2b, and a smart watch 10_2c, vehicle electronic devices 10_3 including display modules, such as an instrument panel, a center fascia, a center information display (CID) arranged on a dashboard, and a room mirror display, and the like.

The substrate mapping sensor according to the embodiments described above may determine not only the presence or absence of a substrate, but also the sagging state and degree of the substrate, thereby minimizing installation space and installation costs.

Effects according to the embodiments are not limited by the above-described contents, and more various other effects are included in the present specification.

Although specific embodiments have been described herein, other embodiments and modifications may be derived from the foregoing descriptions. Therefore, the spirit of the inventive concept should not be limited to the above-described embodiments, and the scope of the claims set forth below, as well as all equivalents or modifications of the claims, should be considered to fall within the scope of the spirit of the inventive concept.

What is claimed is:

1. A substrate mapping sensor detecting a state of a substrate located in a channel within a cassette comprising:
a light transmitting unit located on a side of the cassette; and
a light receiving unit located on another side of the cassette,
wherein the light transmitting unit includes a first light transmitting unit and a second light transmitting unit, which are a pair and located on a side of the channel,
wherein the light receiving unit includes a first light receiving unit and a second light receiving unit, which are a pair and located on another side of the channel,
wherein the first light transmitting unit and the first light receiving unit detect a presence or an absence of the substrate in the channel, and
wherein the second light transmitting unit and the second light receiving unit detect a sagging state of the substrate in the channel.

2. The substrate mapping sensor of claim 1, wherein the first light transmitting unit and the first light receiving unit face each other in a first direction with the channel interposed therebetween.

3. The substrate mapping sensor of claim 1, wherein the first light transmitting unit includes one light transmitting element.

4. The substrate mapping sensor of claim 1, wherein the first light receiving unit includes one light receiving element.

5. The substrate mapping sensor of claim 1, wherein the second light transmitting unit and the second light receiving unit face each other in a first direction with the channel interposed therebetween.

6. The substrate mapping sensor of claim 1, wherein the second light transmitting unit includes first, second, and third light transmitting elements.

7. The substrate mapping sensor of claim 1, wherein the second light receiving unit includes first, second, third, fourth, and fifth light receiving elements.

8. The substrate mapping sensor of claim 1, wherein the sagging state of the substrate is determined by a displacement value of an amount of light reaching the second light receiving unit.

9. The substrate mapping sensor of claim 1, wherein a sagging detection area of the substrate is 5 mm to 13 mm based on a normally loaded substrate.

10. The substrate mapping sensor of claim 1, wherein a distance between a first side of the substrate and the light transmitting unit is 150 mm or less.

11. The substrate mapping sensor of claim 1, wherein a distance between a second side of the substrate and the light receiving unit is 150 mm or less.

12. The substrate mapping sensor of claim 1, wherein the light receiving unit further includes a first indicator light indicating the presence or the absence of the substrate and a second indicator light indicating the sagging state of the substrate.

13. The substrate mapping sensor of claim 1, wherein a light source of the light transmitting unit is infrared.

14. The substrate mapping sensor of claim 1, wherein a light receiving element of the light receiving unit is a photodiode.

15. An electronic device comprising:
a processor; and
a display device including pixels and configured to display an image by the pixels under the control of the processor,
wherein a state of a substrate of the display device is detected by a substrate mapping sensor comprising:
a light transmitting unit located on a side of a cassette; and
a light receiving unit located on another side of the cassette,
wherein the light transmitting unit includes a first light transmitting unit and a second light transmitting unit, which are a pair and located on a side of a channel,
wherein the light receiving unit includes a first light receiving unit and a second light receiving unit, which are a pair and located on another side of the channel,
wherein the first light transmitting unit and the first light receiving unit detect a presence or an absence of the substrate in the channel, and
wherein the second light transmitting unit and the second light receiving unit detect a sagging state of the substrate in the channel.
